(19) United States
(12) Patent Application Publication
(10) Pub. No.: US 2024/0405173 A1
(43) Pub. Date: Dec. 5, 2024

(54) LIGHT EMITTING DEVICE

(71) Applicant: NICHIA CORPORATION, Anan-shi (JP)

(72) Inventors: Yoshiyuki KAGEYAMA, Tokushima-shi (JP); Takahito MORITA, Tokushima-shi (JP); Kiyoko UMEMOTO, Anan-shi (JP)

(73) Assignee: NICHIA CORPORATION, Anan-shi (JP)

(21) Appl. No.: 18/672,863

(22) Filed: May 23, 2024

(30) Foreign Application Priority Data
May 31, 2023 (JP) 2023-089442

(51) Int. Cl. H01L 33/58; H01L 25/075; H01L 33/50; H02N 2/02

(52) U.S. Cl. CPC H01L 33/58; H01L 25/0753; H01L 33/50; H02N 2/028

(57) ABSTRACT

A light emitting device includes a light source having a light emitting surface, and a light shielding member located above the light source and having an opening. The light shielding member is movable between (i) a first position in which the opening overlaps the light emitting surface of the light source in a top view, and (ii) a second position, different from the first position, in which the opening overlaps the light emitting surface of the light source in the top view. Light emission of the light source is controllable under a first condition when the light shielding member is in the first position, and is controllable under a second condition when the light shielding member is in the second position.

### CROSS-REFERENCE TO RELATED APPLICATIONS

This application is based on and claims priority to Japanese Patent Application No. 2023-089442, filed on May 31, 2023, the entire contents of which are incorporated herein by reference.

### TECHNICAL FIELD

The present disclosure relates to a light emitting device.

### BACKGROUND

Light emitting devices that include light emitting elements such as light emitting diodes (LEDs) are known. For example, Japanese Patent Publication No. 2018-081832 describes a light source unit in which a plurality of LEDs are two-dimensionally mounted on a substrate at a high density and the LEDs can be controlled to be individually turned on or off.

### SUMMARY

It is an object of embodiments of the present disclosure to provide a light emitting device that can achieve high definition.

A light emitting device according to one embodiment of the present disclosure includes a light source having a light emitting surface, and a light shielding member disposed above the light source and having an opening. The light shielding member is movable between a first position in which the opening overlaps the light emitting surface of the light source in a top view and a second position in which the opening overlaps the light emitting surface of the light source in the top view and that is different from the first position. Light emission of the light source is controllable under a first condition when the light shielding member is in the first position, and is controllable under a second condition when the light shielding member is in the second position.

### BRIEF DESCRIPTION OF THE DRAWINGS

Other objects and further features of the present invention will be apparent from the following detailed description when read in conjunction with the accompanying drawings, in which:

FIG. 1 is a schematic top view illustrating a configuration of a light emitting device according to a first embodiment;

FIG. 2A is a schematic top view illustrating a light source of the light emitting device according to the first embodiment;

FIG. 2B is a schematic top view illustrating a light shielding member of the light emitting device according to the first embodiment;

FIG. 3 is a schematic cross-sectional view of the light emitting device according to the first embodiment;

FIG. 4 is a schematic top view illustrating some of a plurality of light emitting surfaces according to the first embodiment;

FIG. 5 is a schematic diagram illustrating the operation of the light emitting device according to the first embodiment;

FIG. 6 is a schematic diagram illustrating a first example of the relationship between the movement of the light shielding member and turning-on of the light source;

FIG. 7 is a schematic diagram illustrating a second example of the relationship between the movement of the light shielding member and turning-on of the light source;

FIG. 8 is a schematic diagram illustrating pseudo light emitting surfaces obtained by the operation illustrated in FIG. 5;

FIG. 9 is a schematic top view illustrating of some of a plurality of light emitting surfaces according to a second embodiment;

FIG. 10 is a schematic diagram illustrating a first example of the operation of a light emitting device according to the second embodiment;

FIG. 11 is a schematic diagram illustrating pseudo light emitting surfaces obtained by the operation illustrated in FIG. 10;

FIG. 12 is a schematic diagram illustrating a second example of the operation of the light emitting device according to the second embodiment;

FIG. 13 is a schematic diagram illustrating pseudo light emitting surfaces obtained by the operation in FIG. 12;

FIG. 14 is a schematic diagram illustrating a third example of the operation of the light emitting device according to the second embodiment;

FIG. 15 is a schematic diagram illustrating pseudo light emitting surfaces obtained by the operation in FIG. 14;

FIG. 16 is a schematic cross-sectional view of a light emitting device according to a first modification;

FIG. 17 is a schematic cross-sectional view of a light emitting device according to a second modification;

FIG. 18 is a schematic cross-sectional view of a light emitting device according to a third modification;

FIG. 19 is a schematic cross-sectional view of a light emitting device according to a fourth modification;

FIG. 20 is a schematic cross-sectional view of a light emitting device according to a fifth modification;

FIG. 21 is a schematic cross-sectional view of a light emitting device according to a sixth modification;

FIG. 22 is a schematic cross-sectional view of a light emitting device according to a seventh modification; and

FIG. 23 is a schematic cross-sectional view of a light emitting device according to an eighth modification.

### DETAILED DESCRIPTION

In the following description, light emitting devices according to embodiments of the present disclosure will be described in detail with reference to the accompanying drawings. The following embodiments exemplify the light emitting devices to give a concrete form to the technical ideas of the present disclosure, but the invention is not limited to the described embodiments. In addition, unless otherwise specified, the dimensions, materials, shapes, relative arrangements, and the like of components described in the embodiments are not intended to limit the scope of the present invention thereto, but are described as examples. The sizes, positional relationships, and the like of members illustrated in the drawings may be exaggerated for clearer illustration. Further, in the following description, the same names and reference numerals denote the same or similar members, and a repeated detailed description thereof will be omitted as appropriate. An end view illustrating only a cut surface may be used as a cross-sectional view.

In the drawings, to indicate directions, an orthogonal coordinate system having an X-axis, a Y-axis, and a Z-axis is used. The X-axis, the Y-axis, and the Z-axis are orthogonal to one another. A Z direction along the Z-axis indicates a direction normal to light emitting surfaces of light sources included in the light emitting devices. Each of “along the X-axis,” “along the Y-axis,” and “along the Z-axis” includes a case where an object is at an inclination within a range of ±10° with respect to the corresponding one of the axes. Further, in the embodiments, the term “orthogonal” may include a deviation within ±10° with respect to 90°.

A direction indicated by an arrow in the X direction is referred to as a +X side, and a direction opposite to the +X side is referred to as a −X side. A direction indicated by an arrow in the Y direction is referred to as a +Y side, and a direction opposite to the +Y side is referred to as a −Y side. A direction indicated by an arrow in the Z direction is referred to as an upper side or a +Z side, and a direction opposite to the +Z side is referred to as a −Z side.

The term “top view” as used in the embodiments refers to viewing an object downwardly from the +Z side. Further, in the embodiments, a surface of the object as viewed from the +Z side is referred to as an “upper surface,” and a surface of the object as viewed from the −Z side is referred to as a “lower surface.” However, references to directions or orientations are not intended to limit the orientations of the light emitting devices during use, and the light emitting devices may be used in any orientations.

In the present specification and the claims, if there are multiple components and these components are to be distinguished from one another, the components may be distinguished by adding terms “first,” “second,” and the like before the names of the components. Further, objects to be distinguished may be different between the specification and the claims.

### First Embodiment

### <Example of Overall Configuration of Light Emitting Device According to First Embodiment>

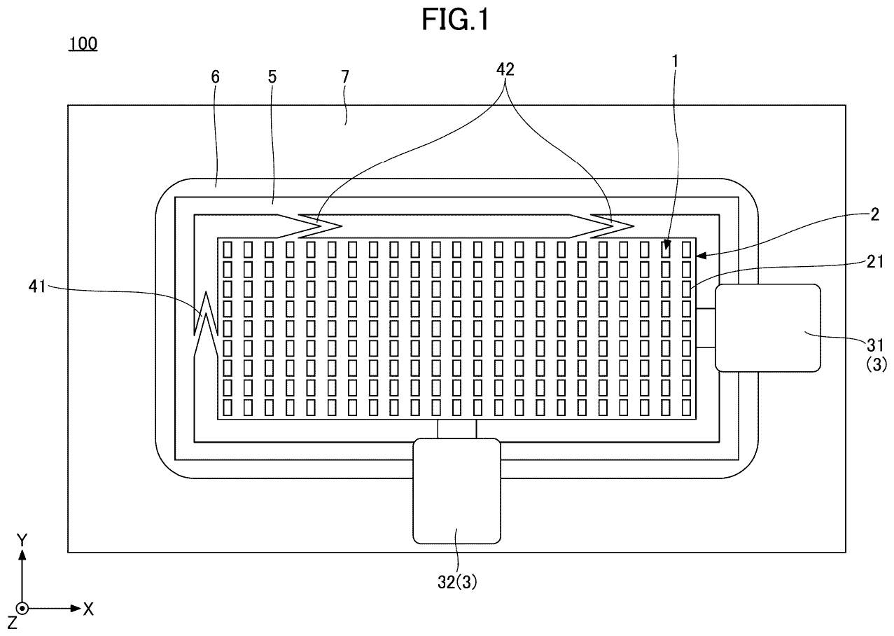

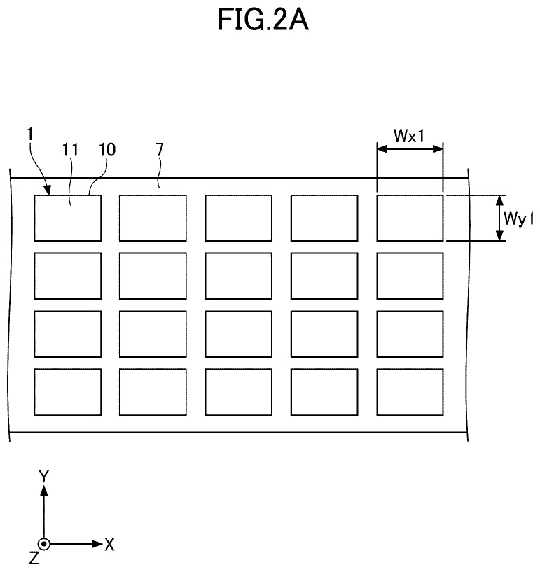

The overall configuration of a light emitting device according to a first embodiment will be described with reference to FIG. 1 through FIG. 2B. FIG. 1 is a schematic top view illustrating an example configuration of a light emitting device 100 according to the first embodiment. FIG. 2A and FIG. 2B are schematic top views illustrating a light source 1 and a light shielding member 2 of the light emitting device 100.

As illustrated in FIG. 1 through FIG. 2B, in the present embodiment, the light emitting device 100 includes the light source 1 and the light shielding member 2. Further, the light emitting device 100 may include an actuator 3, a first elastic member 41, a second elastic member 42, a support member 5, a covering member 6, and a substrate 7.

The light source 1 has a light emitting surface 11. In the examples herein, the light source 1 includes a plurality of light emitting parts 10 arranged in the X direction and the Y direction and having respective light emitting surfaces 11. The light emitting surface 11 of each of the light emitting parts 10 has a substantially rectangular shape in a top view. The light source 1 emits light from each of the light emitting surfaces 11 toward the light shielding member 2. As the light emitting parts 10, light emitting diodes (LEDs) can be used, for example. Further, as the light source 1, a micro-LED array including one-dimensionally or two-dimensionally arranged minute LEDs can be used, for example.

The light shielding member 2 is disposed above the light source 1 and has an opening 21. A portion of the light emitted from the light source 1 exits from the light emitting device 100 through the opening 21, and the other portion of the light emitted from the light source 1 is shielded by the light shielding member 2.

In the examples herein, the light shielding member 2 has a plurality of openings 21 corresponding to the plurality of light emitting parts 10. Each of the openings 21 has a substantially rectangular shape in a top view. Light emitted from each of the light emitting parts 10 passes through a corresponding one of the openings 21 of the light shielding member 2 and exits from the light emitting device 100.

The light shielding member 2 is a flat plate-shaped member composed of a light shielding material such as a metal material or the like. The plurality of openings 21 may be through-holes formed in the light shielding member 2 and arranged corresponding to the plurality of the light emitting parts 10. The through-holes may each have a lateral surface inclined with respect to the upper surface of the light shielding member 2, or may each have a lateral surface substantially perpendicular to the upper surface of the light shielding member 2. For example, each of the through-holes is a columnar region defined by an upper surface, a lower surface, and lateral surfaces perpendicular to the upper surface and the lower surface. The openings 21 are not limited to the through-holes, and may be light transmissive regions through which light can be transmitted. As used herein, the term “light transmissive” means that 60% or more of the light from the light source 1 is transmitted.

In the light emitting device 100, a width Wx2 of the opening 21 in the X direction is preferably smaller than a width Wx1 of the light emitting surface 11 in the X direction. A width Wy2 of the opening 21 in the Y direction is preferably smaller than a width Wy1 of the light emitting surface 11 in the Y direction. Therefore, the opening area Wx2×Wy2 of the opening 21 is preferably smaller than the area Wx1×Wy1 of the light emitting surfacell of the light source 1. In the present embodiment, by setting the opening area Wx2×Wy2 to be smaller than the area Wx1×Wy1, a portion of light emitted from each of the light emitting surfaces 11 passes through a corresponding one of the openings 21, and the other portion of the light can be shielded by the light shielding member 2. Thus, the areas of the light emitting surfaces 11 can be apparently reduced. In the examples herein, the width Wx2 is approximately one-half of the width Wx1, the width Wy2 is approximately one-half of the width Wy1, and the opening area Wx2×Wy2 is approximately one-fourth of the area Wx1×Wy1. In the present embodiment, if the openings 21 have a tapered shape, the width Wx2 indicates the minimum width of the opening 21 in the X direction, the width Wy2 indicates the minimum width of the opening 21 in the Y direction, and the dimension Wx2×Wy2 indicates the narrowest area of the openings 21.

The actuator 3 drives the light shielding member 2. In the examples herein, the actuator 3 includes a first actuator 31 and a second actuator 32. The first actuator 31 moves the light shielding member 2 in the X direction. The second actuator 32 moves the light shielding member 2 in the Y direction.

In the present embodiment, the actuator 3 may be a piezoelectric actuator including a piezoelectric element. The piezoelectric element contains barium titanate, barium zirconate, or the like. The actuator 3 can move the light shielding member 2, disposed to be contactable with one end of the piezoelectric element, by causing the piezoelectric element to expand and contract according to the applied voltage. The one end of the piezoelectric element may be bonded to the light shielding member 2 by an adhesive member or the like. In the present embodiment, the actuator 3 includes the piezoelectric element, and thus, the size of the actuator 3 can be reduced and the configuration of the actuator 3 can be simplified. However, the actuator 3 does not necessarily include the piezoelectric element, and may include an electric motor, an ultrasonic motor, a voice coil motor, or the like.

One end of each of the first elastic member 41 and the second elastic member 42 is connected to the light shielding member 2, and the other end of each of the first elastic member 41 and the second elastic member 42 is connected to the support member 5. Each of the first elastic member 41 and the second elastic member 42 contains a metal material or the like, and is an elastic spring member or the like. Each of the first elastic member 41 and the second elastic member 42 applies a restoring force to the light shielding member 2 that returns the light shielding member 2 to the original position.

For example, when a piezoelectric element of the first actuator 31 expands in the X direction and the light shielding member 2 moves to the −X side, the first elastic member 41 contracts in the X direction. Then, when the piezoelectric element of the first actuator 31 contracts in the X direction from this state, the first elastic member 41 expands in the X direction and applies a restoring force to the light shielding member 2 that returns the light shielding member 2 to the original position in the X direction. Thus, the first elastic member 41 can move the light shielding member 2 to the +X side.

Further, when a piezoelectric element of the second actuator 32 expands in the Y direction and the light shielding member 2 moves to the +Y side, the second elastic member 42 contracts in the Y direction. Then, when the piezoelectric element of the second actuator 32 contracts in the Y direction from this state, the second elastic member 42 expands in the Y direction and applies a restoring force to the light shielding member 2 that returns the light shielding member 2 to the original position in the Y direction. Thus, the second elastic member 42 can move the light shielding member 2 to the −Y side.

However, the light emitting device 100 does not necessarily include the first elastic member 41 and the second elastic member 42. For example, the light shielding member 2 may be bonded to one end of a piezoelectric element of the actuator 3 by an adhesive member or the like such that the light shielding member 2 is movable according to the expansion and contraction of the piezoelectric element.

The support member 5 is a frame-shaped member that is disposed on the upper surface of the covering member 6 and supports the light shielding member 2. The light shielding member 2 is disposed within the frame of the support member 5, and the support member 5 supports the light shielding member 2 via each of the first elastic member 41 and the second elastic member 42. The support member 5 is composed of a metal material, a resin material, or the like. In the example illustrated in FIG. 1, the support member 5, the first elastic member 41, the second elastic member 42, and the light shielding member 2 are monolithic, but at least one of these members may be a separate member. If there are assumed to be two members, the term “separate members” refers to the two members that contact each other and are not bonded to each other, or the two members that are bonded to each other via an adhesive member or the like.

The covering member 6 is a member disposed to cover the upper surface of the substrate 7. As the covering member 6, a resin material containing a filler having a light shielding property can be used, for example. As the resin material, it is preferable to use a base material containing a resin material whose main component is a thermosetting resin such as an epoxy resin, an epoxy-modified resin, a silicone resin, a silicone-modified resin, or a phenol resin. Examples of the filler having a light shielding property include light absorbing materials such as pigments, carbon black, titanium black, and graphite; and light reflective substances such as titanium oxide, zinc oxide, magnesium oxide, magnesium carbonate, magnesium hydroxide, calcium carbonate, calcium hydroxide, calcium silicate, magnesium silicate, barium titanate, barium sulfate, aluminum hydroxide, aluminum oxide, zirconium oxide, and silicon oxide. It is preferable to use one of the above substances alone or a combination of two or more of the above substances. Specifically, as the covering member 6, a white resin having good light reflectivity, a black resin having good light absorbency, a gray resin having light reflectivity and light absorbency, or the like can be used.

The substrate 7 is a flat plate-shaped member on which the plurality of light emitting parts 10 of the light source 1 are disposed. As the substrate 7, for example, an application-specific integrated circuit (ASIC) can be used in which circuits configured to control light emission of the light source 1 and control driving of the light shielding member 2 by the actuator 3 are integrated. The light emitting parts 10 are electrically connected to power-feeding terminals disposed on the substrate 7, and can be turned on by power supplied through the terminals.

Because the substrate 7 is the ASIC, the light source 1, the actuator 3, and their control circuits can be integrated, and thus, the size of the light emitting device 100 can be reduced and the configuration of the light emitting device 100 can be simplified. Further, provision of wiring for the light source 1 and the actuator 3 to the control circuits can be facilitated. However, the substrate 7 need not necessarily be the ASIC, and may be another integrated circuit such as a field-programmable gate array (FPGA). Further, the light source 1 may be mounted on a substrate other than a control circuit such as the ASIC. The control circuit of the light source 1 and the control circuit of the actuator 3 may be distinct control circuits.

### <Example Detailed Configuration in Vicinity of Light Source According to First Embodiment>

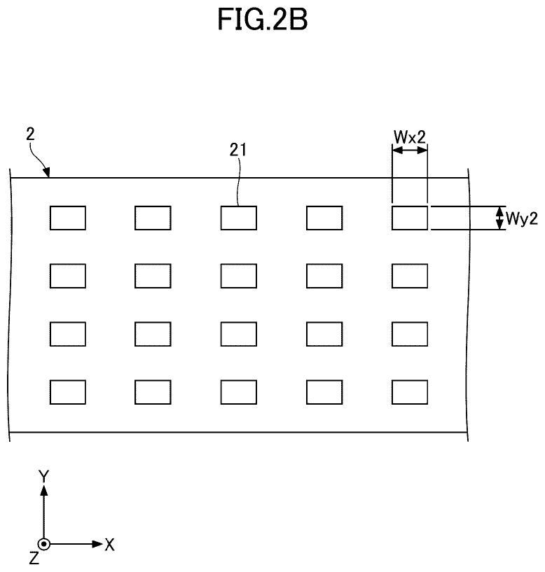

A configuration in the vicinity of the light source 1 according to the first embodiment will be described in detail with reference to FIG. 3. FIG. 3 is a schematic cross-sectional view of the light emitting device 100 including the light emitting parts 10 of the light source 1 and the openings 21 of the light shielding member 2. FIG. 3 depicts four adjacent light emitting parts 10 arranged in the X direction among the plurality of light emitting parts 10 included in the light source 1, and four openings 21 provided in one-to-one correspondence with the four light emitting parts 10.

As illustrated in FIG. 3, in the present embodiment, each of the four light emitting parts 10 includes a light emitting element 12 and a wavelength conversion member 13 disposed on the light emitting element 12. The wavelength conversion member 13 is disposed on the light emitting element 12 such that the entirety of the light emitting element 12 is covered in a top view. The wavelength conversion member 13 may constitute a light emitting surface 11 of the light source 1. With this configuration, the light emitting device 100 can emit mixed light in which the color of light from the light emitting element 12 and the color of light converted by the wavelength conversion member 13 are mixed. The light emitting device 100 may be configured to emit the light whose color is converted by the wavelength conversion member 13 without including the color of the light from the light emitting element 12. If the wavelength conversion member 13 includes a light transmissive layer such as a protective layer on the light shielding member 2 side (on the +Z side), the light transmissive layer included in the wavelength conversion member 13 may constitute the light emitting surface 11 of the light source 1.

The light emitting element 12 includes at least positive and negative element electrodes. The light emitting element 12 is mounted on the substrate 7, and an electrode of the substrate 7 and the electrodes of the light emitting element 12 are electrically connected. The light emitting element 12 preferably includes various semiconductors such as group III-V compound semiconductors and group II-VI compound semiconductors. As the semiconductors, nitride-based semiconductors such as In_{X}Al_{Y}Ga_{1-X-Y}N (0≤X, 0≤Y, X+Y≤1) are preferably used, and InN, AlN, GaN, InGaN, AlGaN, InGaAlN, and the like can also be used. As described above, the light emitting element 12 may be an LED. However, as the light emitting element 12, a laser diode (LD) may be used. The peak emission wavelength of the light emitting element 12 is preferably 400 nm or more and 530 nm or less from the viewpoint of emission efficiency, excitation of a phosphor described later, and the like.

The wavelength conversion member 13 is disposed on the light emitting element 12. The wavelength conversion member 13 has, for example, a substantially rectangular shape in a top view. The wavelength conversion member 13 covers the upper surface of the light emitting element 12. The wavelength conversion member 13 can be formed by using a light-transmissive organic material such as a resin, or a light transmissive inorganic material such as ceramic or glass. As the resin material, a thermosetting resin such as a silicone resin, a silicone-modified resin, an epoxy resin, an epoxy-modified resin, or a phenol resin can be used. Further, a thermoplastic resin such as a polycarbonate resin, an acrylic resin, a methylpentene resin, or a polynorbornene resin can be used for the wavelength conversion member 13. In particular, a silicone resin having high light resistance and heat resistance or a modified resin thereof is suitable. As used herein, the term “light transmissive” means that 60% or more of the light from the light emitting element 12 is preferably transmitted. Further, the wavelength conversion member 13 includes, in the resin described above, a phosphor that converts the wavelength of at least a portion of the light from the light emitting element 12. For example, the wavelength conversion member 13 may be any of the above-described light-transmissive base materials containing a phosphor, a sintered body of a phosphor, or the like. Alternatively, the wavelength conversion member 13 may be a multilayer member in which a phosphor-containing layer is disposed on a formed body formed of resin, ceramic, glass, or the like.

Examples of a phosphor contained in the light transmissive member 13 include yttrium aluminum garnet based phosphors (for example, (Y,Gd)₃(Al,Ga)₅O₁₂:Ce), lutetium aluminum garnet based phosphors (for example, Lu₃(Al,Ga)₅O₁₂:Ce), terbium aluminum garnet based phosphors (for example, Tb₃(Al,Ga)₅O₁₂:Ce), CCA based phosphors (for example, Ca₁₀(PO₄)₆Cl₂:Eu), SAE based phosphors (for example, Sr₄Al₁₄O₂₅:Eu), chlorosilicate based phosphors (for example, CaBMgSi₄O₁₆Cl₂:Eu), silicate based phosphors (for example, (Ba,Sr,Ca,Mg)₂SiO₄:Eu), oxynitride based phosphors such as β-SiAlON based phosphors (for example, (Si,Al)₃(O,N)₄:Eu) and α-SiAlON based phosphors (for example, Ca(Si,Al)₁₂(O,N)₁₆:Eu), nitride based phosphors such as LSN based phosphors (for example, (La,Y)₃Si₆N₁₁:Ce), BSESN based phosphors (for example, (Ba,Sr)₂Si₅N₈:Eu), SLA based phosphors (for example, SrLiAl₃N₄:Eu), CASN based phosphors (for example, CaAlSiN₃:Eu), and SCASN based phosphors (for example, (Sr,Ca)AlSiN₃:Eu), fluoride based phosphors such as KSF based phosphors (for example, K₂SiF₆:Mn), KSAF based phosphors (for example, K₂(Si₁₋ₓAlₓ)F₆₋ₓ:Mn, where x satisfies 0<x<1), and MGF based phosphors (for example, 3.5MgO·0.5MgF₂·GeO₂:Mn), quantum dots having a Perovskite structure (for example, (Cs,FA,MA) (Pb,Sn) (F,Cl,Br,I)₃, where FA and MA represent formamidinium and methylammonium, respectively), II-VI quantum dots (for example, CdSe), III-V quantum dots (for example, InP), and quantum dots having a chalcopyrite structure (for example, (Ag,Cu)(In,Ga)(S,Se)₂). The phosphors described above are particles. One of these phosphors can be used alone, or two or more of these phosphors can be used in combination.

Each of the light emitting parts 10 uses a blue light emitting element as the light emitting element 12. The wavelength conversion member 13 includes a phosphor that converts the wavelength of the light emitted from the light emitting element 12 into the wavelength of yellow. Accordingly, the light emitting parts 10 can emit white light. The wavelength conversion member 13 may include a light scattering substance. As the light scattering substance, titanium oxide, barium titanate, aluminum oxide, silicon oxide, or the like can be used.

As described above, in the light emitting device 100, the light shielding member 2 is disposed above a plurality of light emitting parts 10, and the light shielding member 2 has a plurality of openings 21 corresponding to the plurality of light emitting parts 10. In order for the light emitting device 100 to control light distribution with high definition, an interval between the light emitting surfaces 11 and the light shielding member 2 is preferably shorter than the diameter of the light emitting surfaces 11, and is preferably as short as possible within a range in which the light emitting surfaces 11 do not contact the light shielding member 2. Accordingly, unintended light propagation to an opening 21 corresponding to an adjacent light emitting part 10 can be reduced, and the size of the light emitting device can be further reduced. Specifically, the interval between the light emitting surfaces 11 and the light shielding member 2 is preferably 50 nm or more and 100 μm or less, and more preferably 0.5 μm or more and 50 μm or less.

### <Example of Operation of Light Emitting Device According to First Embodiment>

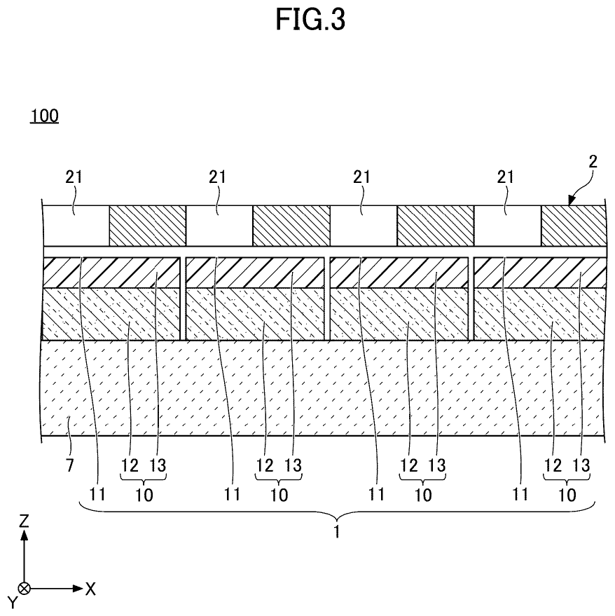

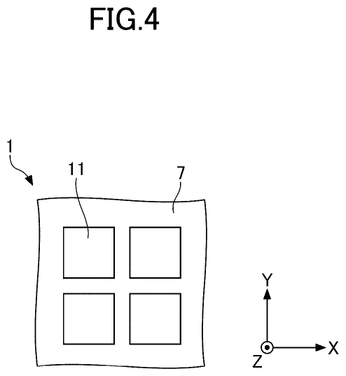

The operation of the light emitting device according to the first embodiment will be described with reference to FIG. 4 through FIG. 8. FIG. 4 is a schematic top view illustrating some (in this example, four light emitting surfaces arranged in a 2×2 matrix) of the plurality of light emitting surfaces 11. FIG. 5 is a schematic diagram illustrating an example of the operation of the light emitting device 100.

FIG. 5 schematically illustrates an example in which the light shielding member 2 disposed above the four light emitting surfaces 11 of FIG. 4 moves in the X direction and in the Y direction, and the relative positions of four openings 21 with respect to the four light emitting surfaces 11 are changed.

In FIG. 5, an arrow 201 indicates the first movement of the light shielding member 2, an arrow 202 indicates the second movement of the light shielding member 2, an arrow 203 indicates the third movement of the light shielding member 2, and an arrow 204 indicates the fourth movement of the light shielding member 2. A state 100-1 indicates a state of the light emitting device before the light shielding member 2 moves, a state 100-2 indicates a state of the light emitting device after the first movement, a state 100-3 indicates a state of the light emitting device after the second movement, and a state 100-4 indicates a state of the light emitting device after the third movement.

In the example illustrated in FIG. 5, in the first movement, the light shielding member 2 moves a distance, substantially equal to the width Wx2 of the openings 21 in the X direction, to the +X side. Subsequently, in the second movement, the light shielding member 2 moves a distance, substantially equal to the width Wy2 of the openings 21 in the Y direction, to the −Y side. Subsequently, in the third movement, the light shielding member 2 moves a distance, substantially equal to the width Wx2 of the openings 21 in the X direction, to the −X side. Subsequently, in the fourth movement, the light shielding member 2 moves a distance, substantially equal to the width Wy2 of the openings 21 in the Y direction, to the +Y side. After the fourth movement of the light shielding member 2, the light emitting device 100 returns to the original state. That is, the light shielding member 2 can make a circulating movement between four positions by moving four times. In the light emitting device 100, the light shielding member 2 can repeatedly make such a circulating movement. As used herein, the term “circulating movement” means that the light shielding member 2 moves while passing through a plurality of positions, and does not mean that the light shielding member 2 moves around the plurality of positions.

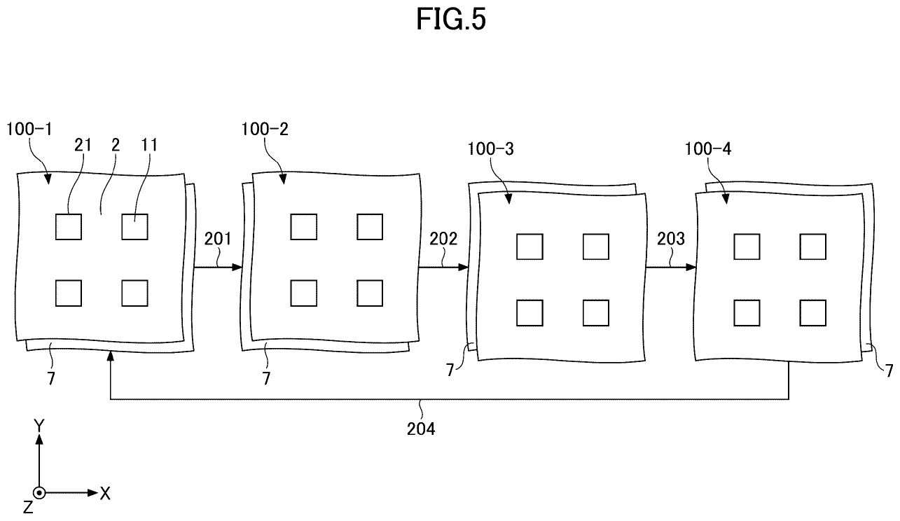

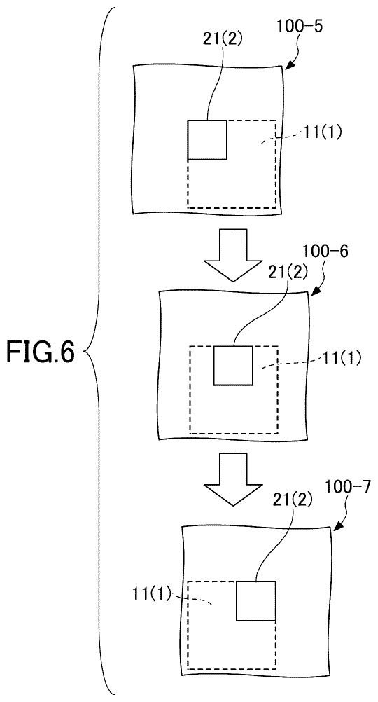

FIG. 6 and FIG. 7 are schematic diagrams each illustrating the relationship between the movement of the light shielding member 2 and turning-on of the light source 1. FIG. 6 is a first example, and FIG. 7 is a second example. The first example is an example in which the light shielding member 2 moves above the light source 1 such that the entire opening 21 overlaps a light emitting surface 11 of the light source 1. The second example is an example in which the light shielding member 2 moves above the light source 1 such that a portion of the opening 21 overlaps the light emitting surface 11 of the light source 1. In FIG. 6, a state 100-5 indicates a state in which the light shielding member 2 is stopped before movement, a state 100-6 indicates a state in which the light shielding member 2 is moving, and a state 100-7 indicates a state in which the light shielding member 2 is stopped after the movement. In FIG. 7, a state 100-8 indicates a state in which the light shielding member 2 is stopped before movement, a state 100-9 indicates a state in which the light shielding member 2 is moving, and a state 100-10 indicates a state in which the light shielding member 2 is stopped after the movement. In the examples herein, in the states 100-5, 100-7, 100-8, and 100-9 in which the light shielding member 2 is stopped, the light source 1 is turned on. Conversely, in the states 100-6 and 100-9 in which the light shielding member 2 is moving, the light source 1 is turned off.

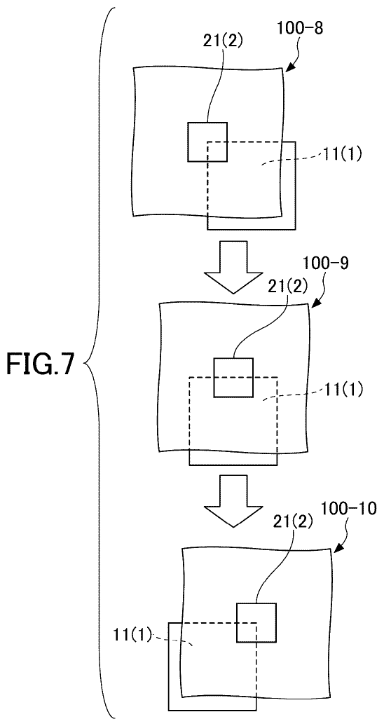

FIG. 8 is a schematic diagram illustrating examples of pseudo light emitting surfaces 111 to 114 obtained by the operation of the light emitting device 100 illustrated in FIG. 5. One light emitting surface 11 is divided into four regions in a pseudo manner by the circulating movement of the light shielding member 2 as illustrated FIG. 5. Thus, the area of each of the pseudo light emitting surfaces 111 to 114 is one-fourth of the area of the one light emitting surface 11.

### <Effects of Light Emitting Device According to First Embodiment>

Effects of the light emitting device 100 according to the first embodiment will be described with continued reference to FIG. 4 through FIG. 8.

In the present embodiment, the light shielding member 2 is movable between a first position in which an opening 21 overlaps a light emitting surface 11 of the light source 1 in a top view, and a second position in which the opening 21 overlaps the light emitting surface 11 of the light source 1 in a top view and that is different from the first position. In addition, light emission of the light source 1 is controllable under a first condition when the light shielding member 2 is in the first position, and is controllable under a second condition when the light shielding member 2 is in the second position. For example, each of the first condition and the second condition may be a condition for performing turning-on of the light source 1 or turning-off of the light source 1.

For example, in the states 100-1 to 100-4 illustrated in FIG. 5, the position of the light shielding member 2 before movement corresponds to the “first position in which the opening 21 overlaps the light emitting surface 11 of the light source 1” in the present embodiment. Further, the position of the light shielding member 2 after the movement corresponds to “the second position in which the opening 21 overlaps the light emitting surface 11 of the light source 1 and that is different from the first position” in the present embodiment. More specifically, the position of the light shielding member 2 in the state 100-1 is an example of the first position in which the opening 21 overlaps the light emitting surface 11 of the light source 1. Further, the position of the light shielding member 2 in the state 100-2 is an example of the second position in which the opening 21 overlaps the light emitting surface 11 of the light source 1 and that is different from the first position.

Further, for example, in FIG. 6, the state 100-5 corresponds to the first position, and the state 100-7 corresponds to the second position. The light source 1 is turned on in the state 100-5 and the state 100-7, and thus each of the first condition and the second condition is a condition for turning on the light source 1.

Further, in FIG. 7, the state 100-8 corresponds to the first position, and the state 100-10 corresponds to the second position. The light source 1 is turned on in the state 100-8 and the state 100-10, and thus each of the first condition and the second condition is a condition for turning on the light source 1.

In the present embodiment, the light shielding member 2 moves between the first position and the second position in which the opening 21 overlaps the light emitting surface 11 in a top view and that are different from each other, and light emission of the light source is controlled under predetermined conditions in the first position and the second position. Therefore, the light emitting surface 11 of the light source 1 can be divided into a plurality of regions in a pseudo manner. For example, as illustrated in FIG. 8, the light emitting surface 11 can be divided into the four regions that are the pseudo light emitting surfaces 111 to 114. The light emitting device 100 can display a desired irradiation pattern, formed by light emitted from the light emitting device 100, by turning on or turning off each of pseudo light emitting surfaces including the pseudo light emitting surfaces 111 to 114 or by individually controlling the amount of light emitted from each of the pseudo light emitting surfaces. The irradiation pattern formed by the light emitted from the light emitting device 100 according to the present embodiment is a monochromatic (for example, white) pattern. A display image formed by the light emitted from the light emitting device 100 according to the present embodiment is a monochromatic (for example, white) image.

In the present embodiment, an irradiation pattern or an image formed by the light emitted from the light emitting device 100 can be controlled with higher definition by dividing the light emitting surface 11 in a pseudo manner. Accordingly, in the present embodiment, the light emitting device 100 that can achieve high definition can be provided. In FIG. 4 to FIG. 8, the light emitting surface 11 is divided into four; however, the number of divisions of the light emitting surface 11 can be appropriately changed according to the application. As the number of divisions of the light emitting surface 11 increases, an irradiation range can be controlled with a larger number of divisions. The light emitting device 100 having such as configuration can be used as a light source of a high-resolution lighting system. Further, higher definition images can be represented in a display device.

Further, for example, if the area of a light emitting surface is reduced by actually dividing the light emitting surface, a predetermined interval needs to be secured between divided light emitting surfaces. Thus, the areas of the divided light emitting surfaces would be reduced by the secured interval, and the amount of light emitted from the light emitting surfaces would be reduced. Conversely, in the present embodiment, the area of the light emitting surface 11 is reduced in a pseudo manner by moving the light shielding member 2 (that is, by controlling the position of the opening 21). Thus, a predetermined interval is not required between the pseudo light emitting surfaces 111 to 114. As a result, according to the present embodiment, as compared to the areas of the plurality of light emitting surfaces obtained by actually dividing the light emitting surface, the area of each of the pseudo light emitting surfaces 111 to 114 can be increased, and the amount of light emitted from each of the pseudo light emitting surfaces 111 to 114 can be increased. Accordingly, the light emitting device 100 that can control light distribution with high definition and high light utilization efficiency can be provided.

Further, in the present embodiment, the light emitting device 100 includes the actuator 3, thereby allowing the light shielding member 2 to move. In the present embodiment, the light shielding member 2 moves above the light source 1. Thus, the light emitting device 100 that can control light emitted from the light source 1 with high definition can be provided.

Further, in the present embodiment, as described with reference to FIG. 6 and FIG. 7, the light source 1 is turned off while the light shielding member 2 is moving. Thus, the light emitted from the light emitting device 100 is less likely to move due to the movement of the light shielding member 2, and the light emitted from the light emitting device 100 can be stabilized. However, the light emitting device 100 does not necessarily turn off the light source 1 while the light shielding member 2 is moving.

Further, in the present embodiment, the opening area of the opening 21 is smaller than the area of the light emitting surface 11 of the light source 1. By making the opening area of the opening 21 smaller than the area of the light emitting surface 11, the light shielding member 2 can be moved with the opening 21 being located within the light emitting surface 11 in a top view, and thus the light emitting surface 11 can be divided into a plurality of regions in a pseudo manner.

Further, in the present embodiment, it is preferable that the position of the opening 21 when the light shielding member 2 is in the first position does not overlap the position of the opening 21 when the light shielding member 2 is in the second position in a top view. Accordingly, light passing through the opening 21 when the light shielding member 2 is in the first position and light passing through the opening 21 when the light shielding member 2 is in the second position are less likely to overlap each other after being emitted from the light emitting device 100. As a result, the contrast of an irradiation pattern or an image formed by the light emitted from the light emitting device 100 can be enhanced. The position of the opening 21 when the light shielding member 2 is in the first position and the position of the opening 21 when the light shielding member 2 is in the second position may partially overlap each other.

Further, in the present embodiment, as described above, the light source 1 may include a plurality of light emitting parts 10 each having the light emitting surfaces 11, and the light shielding member 2 may have a plurality of openings 21 corresponding to the plurality of light emitting parts 10. As the number of the light emitting parts 10 of the light source 1 increases, the light emitting device 100 can control light distribution with higher definition. However, the light source 1 does not necessarily include the plurality of light emitting parts 10. In the present embodiment, even if the light source 1 includes one light emitting part 10, the light emitting device 100 can control light distribution with higher definition by including the light shielding member 2 that has an opening 21 corresponding to the one light emitting part 10.

Further, in the present embodiment, an opening 21 of the light shielding member 2 overlaps a corresponding light emitting surface 11 of the light source 1, and the light shielding member 2 is movable between a plurality of positions above the light emitting surface 11. Turning on or off the light source 1 is controllable in synchronization with the opening 21 being located at each of the plurality of positions. Accordingly, light passing through the opening 21 when the light shielding member 2 is in the first position and light passing through the opening 21 when the light shielding member 2 is in the second position are less likely to overlap each other after being emitted from the light emitting device 100. As a result, the contrast of an irradiation pattern or an image formed by the light emitted from the light emitting device 100 can be enhanced.

Further, in the present embodiment, the plurality of positions may include the first position and the second position, and the light shielding member 2 may make a circulating movement between the plurality of positions including the first position and the second position. A period of time during which the light shielding member 2 moves from the first position to the second position is shorter than a cycle of the circulating movement of the light shielding member 2. The positions of the light shielding member 2 in the states 100-1 to 100-4 illustrated in FIG. 5 correspond to the “plurality of positions” in the present embodiment. By setting the period of time during which the light shielding member 2 moves from the first position to the second position to be shorter than the cycle of the circulating movement of the light shielding member 2, an irradiation pattern or an image formed by light from pseudo light emitting surfaces can be dynamically changed for each cycle of the circulating movement of the light shielding member 2. Accordingly, in the present embodiment, a dynamic irradiation pattern or a moving image can be formed with high definition by the light emitted from the light emitting device 100.

Further, in the present embodiment, the cycle of the circulating movement of the light shielding member 2 may be a natural number multiple of the period of time during which the light shielding member 2 moves from the first position to the second position. Thus, the circulating movement of the light shielding member 2 can be synchronized with the movement of the light shielding member 2 from the first position to the second position. Accordingly, in the present embodiment, a dynamic irradiation pattern or a moving image can be formed with high definition by the light emitted from the light emitting device 100.

Further, in the present embodiment, the amount of light emitted from the light emitting device 100 can be adjusted by adjusting the area where the opening 21 overlaps the light emitting surface 11. Accordingly, the freedom degree of the light adjustment can be increased.

### Second Embodiment

Next, a light emitting device according to a second embodiment will be described. The same names and reference numerals as those of the above-described embodiment refer to the same or similar members or components, and a detailed description thereof will be omitted as appropriate. The same applies to embodiments as will be described later.

The second embodiment differs from the first embodiment in that the light emitting device according to the second embodiment can emit light of multiple colors, that is, multi-color light.

### <Example Configuration of Light Source 1 According to Second Embodiment>

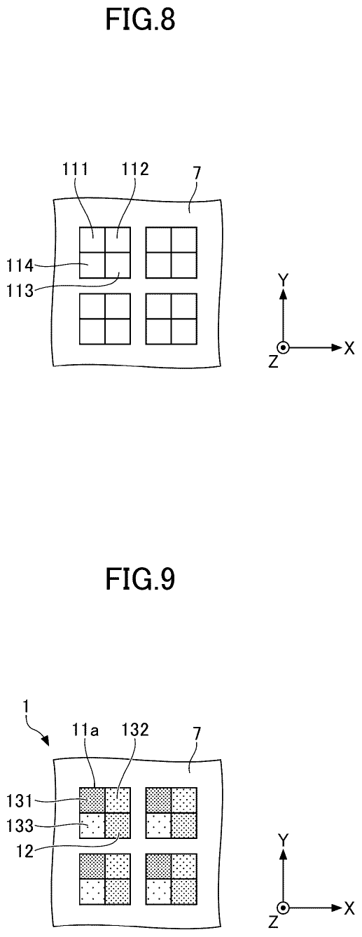

FIG. 9 is a schematic top view illustrating an example of some of a plurality of light emitting surfaces 11a included in a light source 1 according to the second embodiment. The light source 1 includes a light emitting element 12 and wavelength conversion members 131 to 133. The wavelength conversion members 131 to 133 are disposed on the light emitting element 12 such that a portion of the light emitting element 12 is exposed in a top view. The light emitting element 12 and the wavelength conversion members 131 to 133 form a light emitting surface 11a of the light source 1. The wavelength conversion members 131 to 133 correspond to a plurality of wavelength conversion members having different peak emission wavelengths. The wavelength conversion members 131 to 133 are disposed at positions that do not overlap each other in a top view.

In the present embodiment, the light emitting element 12 emits blue light. The wavelength conversion member 131 converts almost all light incident from the light emitting element 12 into red light, and emits the red light. The wavelength conversion member 132 converts almost all light incident from the light emitting element 12 into green light, and emits the green light. The wavelength conversion member 133 converts a portion of light incident from the light emitting element 12 into yellow light, and emits white light in which blue light and yellow light are mixed.

In FIG. 9. a portion where the light emitting element 12 is displayed is a portion of the light emitting element 12 on which the wavelength conversion members 131 to 133 are not disposed and that is exposed. Blue light is emitted from the exposed portion of the light emitting element 12 as is, that is, without passing through the wavelength conversion members 131 to 133.

### <Example of Operation of Light Emitting Device According to Second Embodiment>

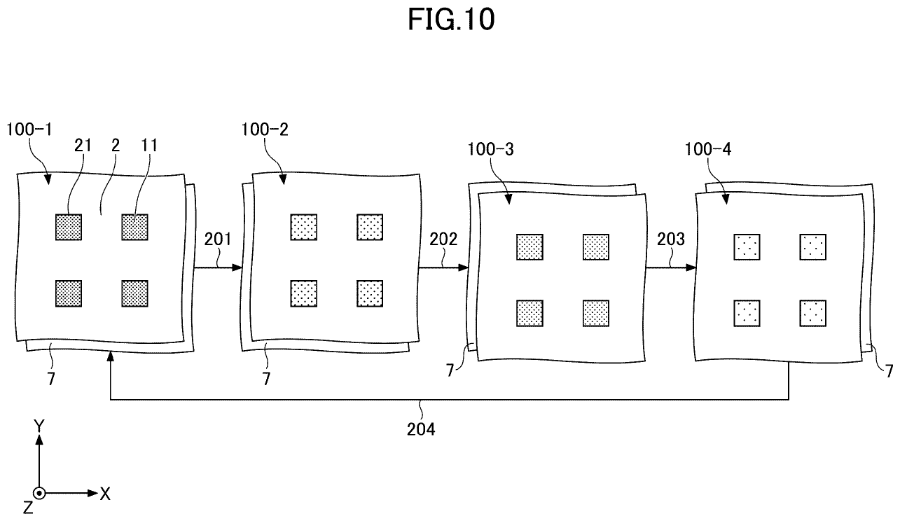

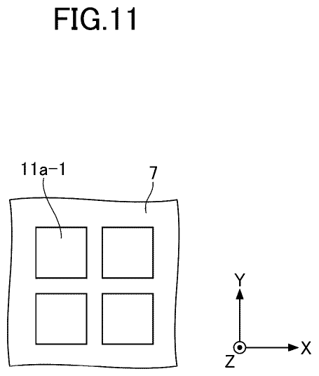

The operation of the light emitting device according to the second embodiment will be described with reference to FIG. 10 and FIG. 11. FIG. 10 is a schematic diagram illustrating a first example of the operation of the light emitting device according to the second embodiment.

FIG. 10 illustrates an example in which a light shielding member 2 disposed above four light emitting surfaces 11a of FIG. 9 moves in the X direction and in the Y direction, and the relative positions of four openings 21 with respect to the four light emitting surfaces 11a are changed.

In a state 100-1, the positions of openings 21 overlap the positions of wavelength conversion members 131 in a top view, and thus red lights from the wavelength conversion members 131 pass through the openings 21. In a state 100-2, the positions of the openings 21 overlap the positions of wavelength conversion members 132 in a top view, and thus, green lights from the wavelength conversion members 132 pass through the openings 21. In a state 100-3, the positions of the openings 21 overlap the positions of portions of the light emitting elements 12 exposed from the wavelength conversion members 131 to 133 in a top view, and thus blue light from the light emitting elements 12 passes through the openings 21. In a state 100-4, the positions of the openings 21 overlaps the positions of the wavelength conversion members 133 in a top view, and thus yellow light from the wavelength conversion members 133 passes through the openings 21.

FIG. 11 is a schematic diagram illustrating examples of pseudo light emitting surfaces 11a-1 obtained by the operation of the light emitting device according to the second embodiment illustrated in FIG. 10. The pseudo light emitting surfaces 11a-1 can emit red light, green light, blue light, and white light that have passed through the openings 21 in one cycle of the circulating movement of the light shielding member 2 illustrated in FIG. 10. At this time, the red light, the green light, the blue light, and the white light are emitted from the pseudo light emitting surfaces 11a-1 at different timings; however, the lights can be visually recognized as if the lights are emitted simultaneously (that is, as mixed color light) because the light shielding member 2 makes the circulating movement at a high speed.

The light emitting device according to the second embodiment can control the color of light emitted from each of the pseudo light emitting surfaces 11a-1 to be a desired color by controlling turning-on or turning-off of the light source 1 or by controlling the amount of light emitted from the light source in each of the states 100-1 to 100-4. Further, the light emitting device according to the second embodiment can form a multi-color irradiation pattern or image by light emitted from the light emitting device by individually controlling the color of light emitted from each of the pseudo light emitting surfaces 11a-1. Further, in the light emitting device according to the second embodiment, each one of the light emitting surfaces 11a is divided into four in a pseudo manner, such that the pseudo light emitting surfaces 11a-1 are generated. Thus, a multi-color irradiation pattern or image can be formed with higher definition as compared to when each one of light emitting surfaces is not divided in a pseudo manner.

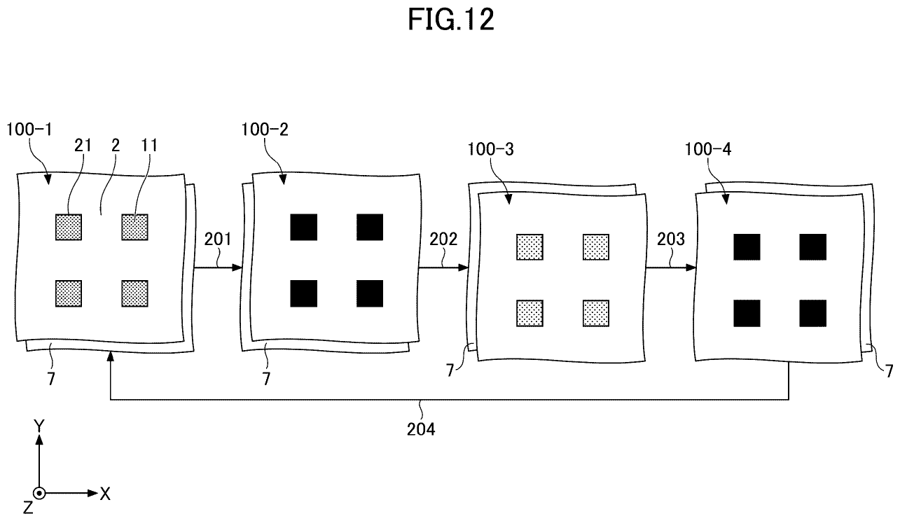

FIG. 12 is a schematic diagram illustrating a second example of the operation of the light emitting device according to the second embodiment. The second example differs from the first example in that the light source 1 is turned off in each of the state 100-2 and the state 100-4.

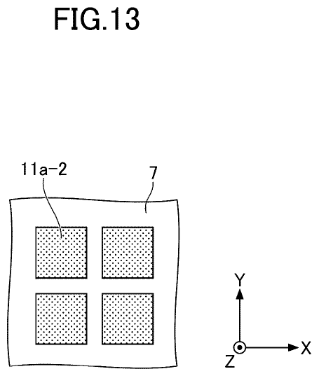

FIG. 13 is a schematic diagram illustrating examples of pseudo light emitting surfaces 11a-2 obtained by the operation of the light emitting device according to the second embodiment illustrated in FIG. 12. The pseudo light emitting surfaces 11a-2 emit purple light by mixing red light and blue light that have passed through the openings 21 in one cycle of the circulating movement of the light shielding member 2 in FIG. 12. In this manner, the light emitting device according to the second embodiment can generate the pseudo light emitting surfaces that emit light of various colors by mixing the colors of lights from the wavelength conversion members 131 to 133 and the light emitting elements 12.

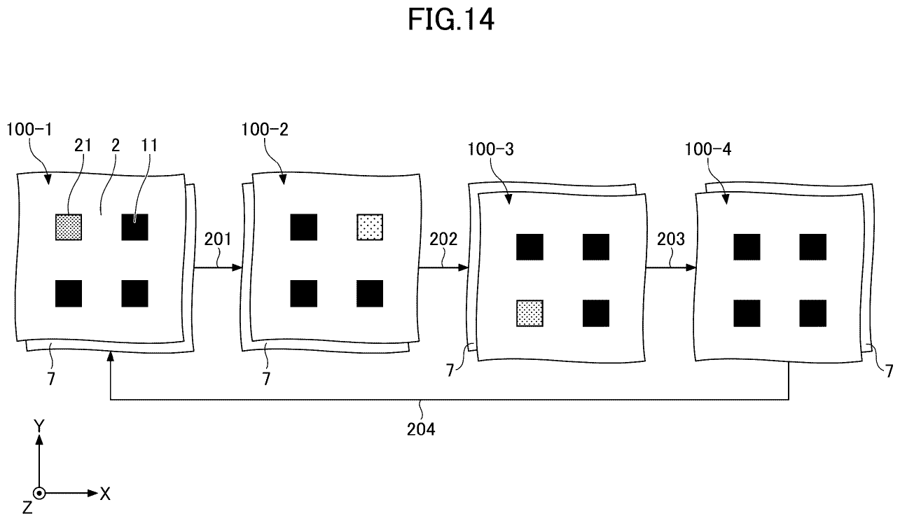

FIG. 14 is a schematic diagram illustrating a third example of the operation of the light emitting device according to the second embodiment. The third example differs from the first example and the second example in that some of a plurality of light emitting surfaces 11a are turned on in each of the states 100-1 to 100-3, and all of the plurality of light emitting surfaces 11a are turned off in the state 100-4.

Specifically, in the state 100-1, only one of four light emitting surfaces 11a is turned on, thereby allowing red light to pass through an opening 21. In state 100-2, only one of the four light emitting surfaces 11a is turned on, thereby allowing green light to pass through an opening 21. In state 100-3, only one of the four light emitting surfaces 11a is turned on, thereby allowing blue light to pass through an opening 21. In state 100-4, the four light emitting surfaces 11a are turned off.

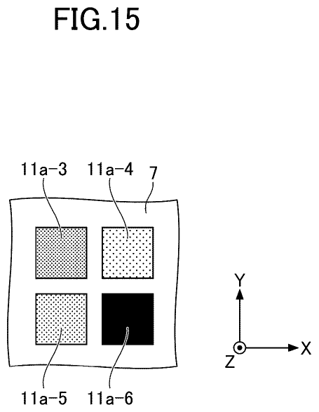

FIG. 15 is a schematic diagram illustrating examples of pseudo light emitting surfaces 11a-3 to 11a-6 obtained by the operation of the light emitting device according to the second embodiment illustrated in FIG. 14. The pseudo light emitting surface 11a-3 emits the red light obtained in one cycle of the circulating movement of the light shielding member 2 illustrated in FIG. 14. The pseudo light emitting surface 11a-4 emits the green light obtained in one cycle of the circulating movement of the light shielding member 2. The pseudo light emitting surface 11a-5 emits the blue light obtained in one cycle of the circulating movement of the light shielding member 2. The pseudo light emitting surface 11a-6 does not emit light in one cycle of the circulating movement of the light shielding member 2. Thus, no light is emitted from the pseudo light emitting surface 11a-6. The amount of light emitted from each of the pseudo light emitting surfaces 11a-3 to 11a-5 can be controlled by, for example, pulse width modulation (PWM) or the like. In this manner, the light emitting device according to the second embodiment can generate the pseudo light emitting surfaces having different peak emission wavelengths by individually controlling light emission of each of the light emitting surfaces 11a in each of the states 100-1 to 100-4.

As described above, in the present embodiment, light of various colors can be emitted from pseudo light emitting surfaces, and a multi-color irradiation pattern or image can be formed by light emitted from the light emitting device.

The configuration of the light emitting device according to the second embodiment is not limited to a configuration in which the light source 1 includes wavelength conversion members 131 to 133 on a light emitting element 12 such that a portion of the light emitting element 12 is exposed in a top view. For example, in the light emitting device according to the second embodiment, the light source 1 may include a wavelength conversion member on a light emitting element 12 such that the wavelength conversion member covers the entire light emitting element 12. In this case, the wavelength conversion member may include a plurality of wavelength conversion members having different peak emission wavelengths, and the plurality of wavelength conversion members may be arranged at positions that do not overlap each other in a top view. With such a configuration, substantially the same effects as those of the light emitting device described with reference to FIG. 9 through FIG. 15 can be obtained.

### Modifications

Light emitting devices according to various modifications of the embodiments will be described below. Among the light emitting devices according to the plurality of modifications described below, any light emitting device other than light emitting devices that include a plurality of wavelength conversion members having different peak emission wavelengths can be applied to the above-described first embodiment. Further, among the light emitting devices according to the plurality of modifications described below, any of the light emitting devices that include the plurality of wavelength conversion members having the different peak emission wavelengths can be applied to the above-described second embodiment.

### First Modification

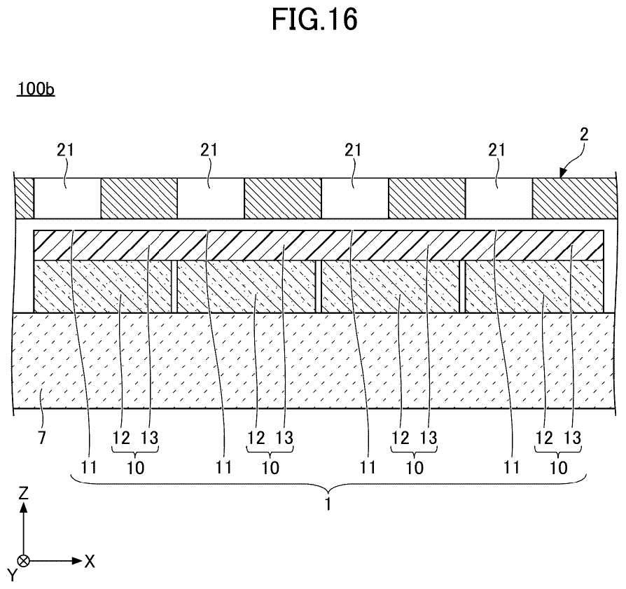

FIG. 16 is a schematic cross-sectional view of a light emitting device 100b according to a first modification. FIG. 16 schematically illustrates a cross section of the light emitting device 100b including light emitting parts 10 of a light source 1 and openings 21 of a light shielding member 2.

As illustrated in FIG. 16, the first modification differs from the first embodiment in that wavelength conversion members 13 included in the plurality of respective light emitting parts 10 are connected to each other.

In the present modification, the wavelength conversion members 13 included in the plurality of respective light emitting parts 10 are connected, so that a process of disposing the wavelength conversion members 13 on the light emitting element 12 can be facilitated, and thus, the light emitting device 100b can be easily manufactured. The other effects are substantially the same as those of the first embodiment.

### Second Modification

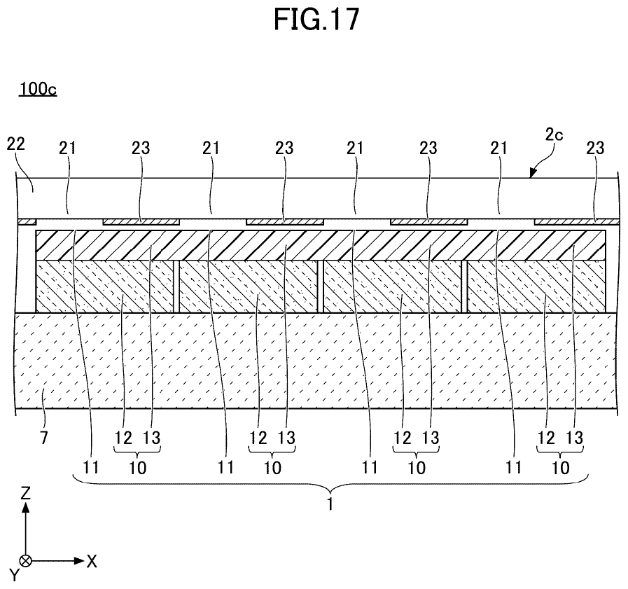

FIG. 17 is a schematic cross-sectional view of a light emitting device 100c according to a second modification. FIG. 17 schematically illustrates a cross section of the light emitting device 100c including light emitting parts 10 of a light source 1 and openings 21 of a light shielding member 2c.

As illustrated in FIG. 17, the second modification differs from the first modification in that the light shielding member 2c of the light emitting device 100c includes a light transmissive member 22 and a light shielding film 23 disposed on the light transmissive member 22, and regions of the light transmissive member 22 on which the light shielding film 23 is not disposed serve as openings 21.

The light transmissive member 22 is composed of a resin material, a glass material, or the like. The light transmissive member 22 preferably has a transmittance of 60% or more with respect to light emitted from the light emitting parts 10.

The light shielding film 23 is composed of a metal material, a resin material, or the like. The light shielding film 23 preferably has a light-shielding rate of 80% or more, and even more preferably has a light-shielding rate of 90% or more. In the example illustrated in FIG. 17, the light shielding film 23 is disposed on the lower surface (the surface on the −Z side) of the light transmissive member 22. However, the light shielding film 23 may be disposed on one or both of the upper surface and the lower surface of the light transmissive member 22.

In the present modification, the openings 21 can be formed by a film deposition process such as a semiconductor process. Thus, the openings 21 highly accurately positioned and having highly accurate shapes can be formed in the light shielding member 2c. The other effects are substantially the same as those of the first modification.

### Third Modification

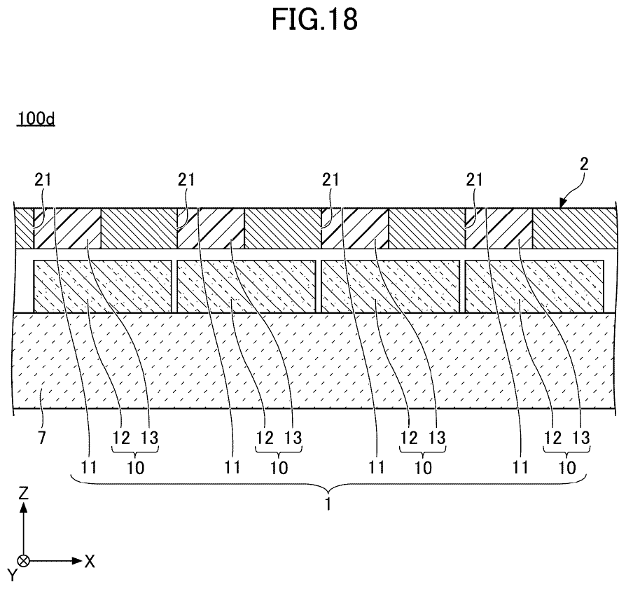

FIG. 18 is a schematic cross-sectional view of a light emitting device 100d according to a third modification. FIG. 18 schematically illustrates a cross section of the light emitting device 100d including light emitting parts 10 of a light source 1 and openings 21 of a light shielding member 2.

As illustrated in FIG. 18, the third modification differs from the first embodiment in that wavelength conversion members 13 are disposed within the openings 21 of the light shielding member 2.

In the present modification, the wavelength conversion members 13 are disposed within the openings 21 by arranging the wavelength conversion members 13 inside the openings 21. The thickness of the wavelength conversion members 13 disposed within the openings 21 is not necessarily the same as the thickness of the openings 21.

In the present modification, the wavelength conversion members 13 are disposed within the openings 21. Thus, a space where the wavelength conversion members 13 are disposed between light emitting elements 12 and the light shielding member 2 can be reduced. Accordingly, by effectively utilizing the space, the light emitting device 100d with a reduced size can be provided. The other effects are substantially the same as those of the first embodiment.

### Fourth Modification

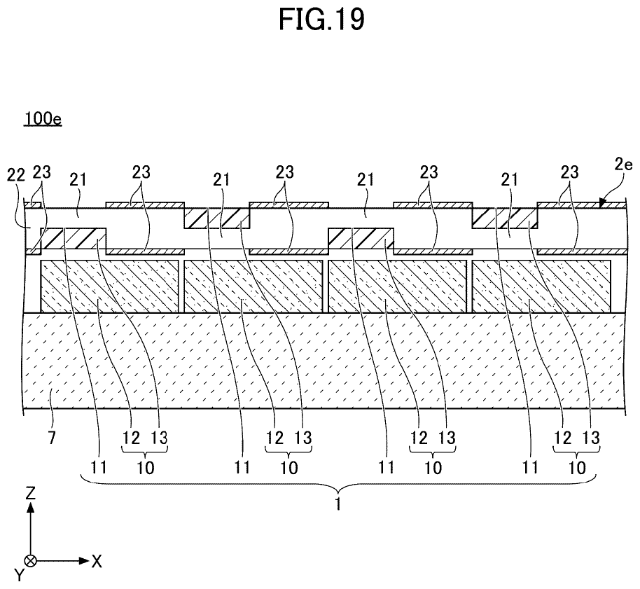

FIG. 19 is a schematic cross-sectional view of a light emitting device 100e according to a fourth modification. FIG. 19 schematically illustrates a cross section of the light emitting device 100e including light emitting parts 10 of a light source 1 and openings 21 of a light shielding member 2e.

The fourth modification differs from the second embodiment in that the light shielding member 2e of the light emitting device 100e includes a light transmissive member 22 and a light shielding film 23 disposed on the light transmissive member 22, and regions of the light transmissive member 22 on which the light shielding film 23 is not disposed serve as the openings 21. In addition, the fourth modification differs from the second embodiment in that wavelength conversion members 13 are disposed on one or both of the upper surface and the lower surface of the light transmissive member 22 of the light shielding member 2e.

In the example illustrated in FIG. 19, light shielding films 23 are formed on both the upper surface and the lower surface of the light transmissive member 22 of the light shielding member 2e, and wavelength conversion members 13 are disposed on both the upper surface and the lower surface of the light transmissive member 22. Wavelength conversion members 13 disposed on the upper surface of the light transmissive member 22 have peak emission wavelengths different from those of wavelength conversion members 13 disposed on the lower surface of the light transmissive member 22.

In the present modification, by disposing the wavelength conversion members 13 on the light transmissive member 22 of the light shielding member 2e, a space where the wavelength conversion members 13 are disposed between light emitting elements 12 and the light shielding member 2e can be reduced. Accordingly, the space can be effectively used, and thus, a light emitting device 100e with a reduced size can be provided. The other effects are substantially the same as those of the second embodiment.

### Fifth Modification

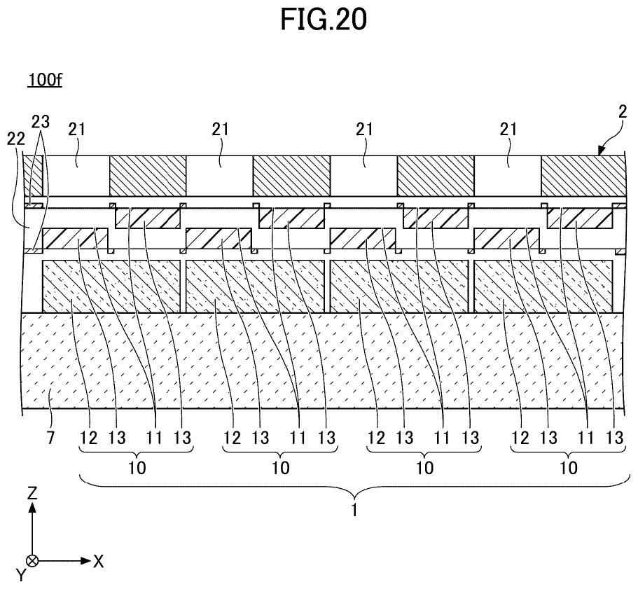

FIG. 20 is a schematic cross-sectional view of a light emitting device 100f according to a fifth modification. FIG. 20 schematically illustrates a cross section of the light emitting device 100f including light emitting parts 10 of a light source 1 and openings 21 of a light shielding member 2.

The fifth modification differs from the second embodiment in that, in addition to the light shielding member 2 having the openings 21, the light emitting device 100f further includes a light transmissive member 22, and a light shielding film 23 is disposed on one or both of the upper surface and the lower surface of the light transmissive member 22.

In the example illustrated in FIG. 20, the light transmissive member 22 is disposed between the light shielding member 2 and light emitting elements 12. A plurality of the light shielding films 23 are disposed on both the upper surface and the lower surface of the light transmissive member 22. Further, each of the upper surface and the lower surface of the light transmissive member 22 has regions on which the light shielding films 23 are not disposed, and these regions are arranged at substantially the same intervals as the intervals at which the openings 21 are formed. Further, wavelength conversion members 13 are disposed on the upper surface and the lower surface of the light transmissive member 22. Wavelength conversion members 13 disposed on the upper surface of the light transmissive member 22 have peak emission wavelengths different from those of wavelength conversion members 13 disposed on the lower surface of the light transmissive member 22. The light transmissive member 22 may be disposed such that the light shielding member 2 is interposed between the light transmissive member 22 and the light emitting elements 12.

In the present modification, substantially the same effects as those of the second embodiment can be obtained.

### Sixth Modification

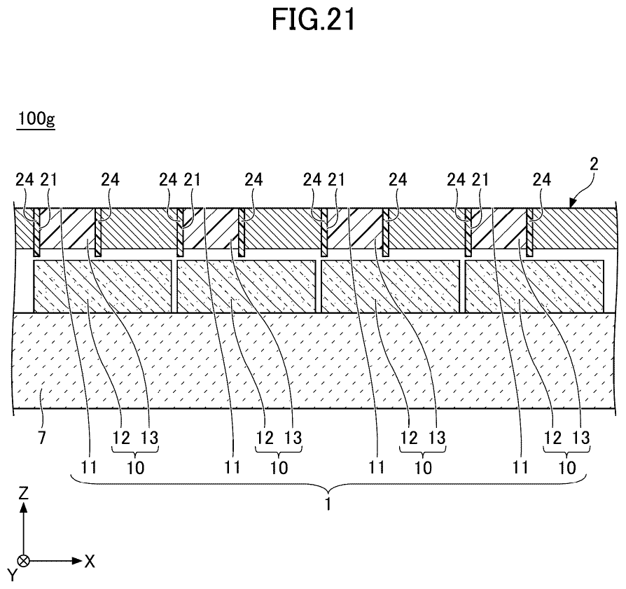

FIG. 21 is a schematic cross-sectional view of a light emitting device 100g according to a sixth modification. FIG. 21 schematically illustrates a cross section of the light emitting device 100g including light emitting parts 10 of a light source 1 and openings 21 of a light shielding member 2.

The sixth modification differs from the third modification in that the light emitting device 100g includes walls 24 disposed around the plurality of respective openings 21 in a top view, and at least portions of the walls 24 are located between the light source 1 and the light shielding member 2.

The walls 24 are tubular members having a substantially rectangular shape in a top view. The walls 24 are disposed in the openings 21. However, in the light shielding member 2, the walls 24 may be constituted by outer edge portions of the openings 21. The outer edge portions of the openings 21 are formed so as to protrude toward light emitting elements 12.

The walls 24 are composed of a metal material, a resin material, or the like. The walls 24 has a light shielding property. The walls 24 preferably has a light-shielding rate of 80% or more, and even more preferably has a light-shielding rate of 90% or more.

In the present modification, the light emitting device 100g includes the walls 24, and thus crosstalk between light beams emitted from the plurality of light emitting parts 10 can be reduced. Therefore, the contrast of an irradiation pattern or an image formed by light emitted from the light emitting device 100g can be enhanced. The other effects are substantially the same as those of the third modification. The present modification can be combined with the third modification or the fifth modification.

### Seventh Modification

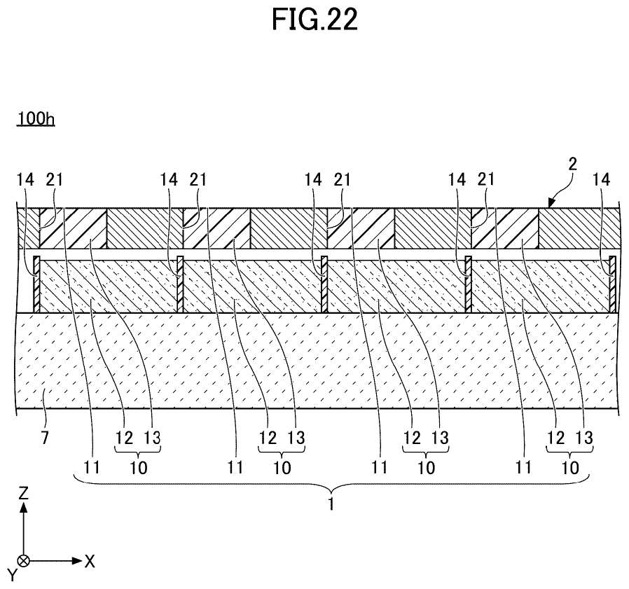

FIG. 22 is a schematic cross-sectional view of a light emitting device 100h according to a seventh modification. FIG. 22 schematically illustrates a cross section of the light emitting device 100h including light emitting parts 10 of a light source 1 and openings 21 of a light shielding member 2.

The seventh modification differs from the third modification in that the light emitting device 100h includes partition walls 14 disposed around a plurality of respective light emitting elements 12 in a top view.

The partition walls 14 are tubular portions having a substantially rectangular shape and formed around the respective light emitting elements 12 in a top view. Portions of the partition walls 14 may protrude toward the light shielding member 2 with respect to the upper surface of the light emitting elements 12, such that the portions of the partition walls 14 are located between the light shielding member 2 and the light emitting elements 12.

The partition walls 14 are composed of a metal material, a resin material, or the like. The partition walls 14 has a light shielding property. The partition walls 14 has a light-shielding rate of 80% or more, and even more preferably has a light-shielding rate of 90% or more.

In the present modification, the light emitting device 100h includes the partition walls 14, and thus crosstalk between light beams emitted from the plurality of light emitting parts 10 can be reduced. Therefore, the contrast of an irradiation pattern or an image formed by light emitted from the light emitting device 100h can be enhanced. The other effects are substantially the same as those of the third modification. The present modification can be combined with the third modification, the fourth modification, or the fifth modification.

### Eighth Modification

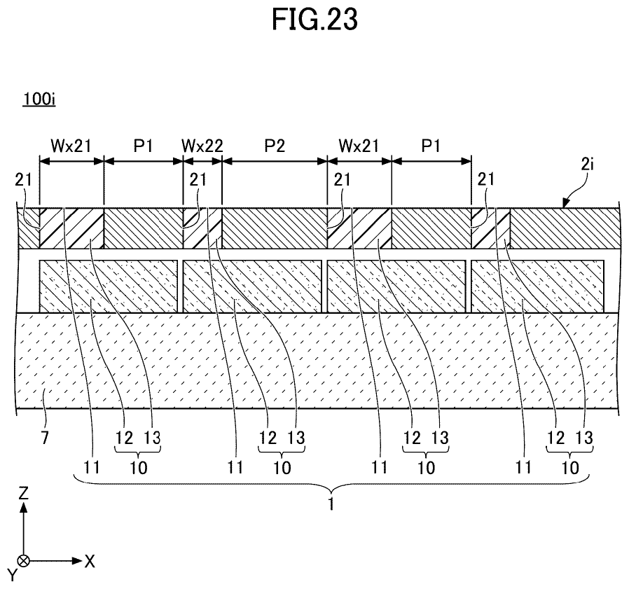

FIG. 23 is a schematic cross-sectional view of a light emitting device 100i according to an eighth modification. FIG. 23 schematically illustrates a cross section of the light emitting device 100i including light emitting parts 10 of a light source 1 and openings 21 of a light shielding member 2i.

The eighth modification differs from the third modification in that the openings 21 of the light shielding member 2i included in the light emitting device 100i are arranged at different intervals and have different widths.

In the example illustrated in FIG. 23, the intervals between the openings 21 of the light shielding member 2i include an interval P1 and an interval P2. Further, the widths of the openings 21 in the X direction include a width Wx21 and a width Wx22.

In the present modification, substantially the same effects as those of the third modification can be obtained. Further, in another aspect, the following can be said. That is, in a light emitting device according to an embodiment including a plurality of openings 21 and a plurality of light emitting surfaces 11, the openings 21 do not necessarily have the same width in the X direction or the Y direction as long as the areas of the openings 21 are smaller than the areas of the light emitting surfaces 11 of a light source 1. Further, in the light emitting device according to the embodiment including the plurality of openings 21 and the plurality of light emitting surfaces 11, the openings 21 are not necessarily arranged at the same interval as long as the areas of the openings 21 are smaller than the areas of the light emitting surfaces 11 of the light source 1.

Although embodiments have been described in detail above, the present disclosure is not limited to the above-described embodiments, and various modifications and substitutions can be made to the above-described embodiments without departing from the scope described in the claims.

Numbers such as ordinal numbers and quantities used in the description of the embodiments are all provided as examples to describe the techniques of the present disclosure, but the present disclosure is not limited to the provided examples of the numbers. In addition, the connection relationships between the components is illustrated for describing the techniques of the present disclosure, but the connection relationships for implementing the functions of the present disclosure is not limited thereto.

The light emitting devices according to the present disclosure can control light distribution with high definition, and thus can be suitably used as display devices such as projectors and displays, lighting devices for vehicles such as automobiles, trains, and bicycles, lighting devices for aerial vehicles such as helicopters and drones, various indoor or outdoor lighting devices, lighting devices such as flashlights worn or held by a person, or the like. If the light emitting devices are used as lighting devices for vehicles, the application of the light emitting devices is not limited to vehicle headlights, and the light emitting devices can be used for various applications such as communication lamps and daytime running lamps.

According to an embodiment of the present disclosure, a light emitting device that can achieve high definition can be provided.

What is claimed is:

1. A light emitting device comprising:
a light source having a light emitting surface; and
a light shielding member located above the light source and having an opening, wherein:
the light shielding member is movable between (i) a first position in which the opening overlaps the light emitting surface of the light source in a top view, and (ii) a second position, different from the first position, in which the opening overlaps the light emitting surface of the light source in the top view, and
light emission of the light source is controllable under a first condition when the light shielding member is in the first position, and is controllable under a second condition when the light shielding member is in the second position.

2. The light emitting device according to claim 1, wherein:
an opening area of the opening is smaller than an area of the light emitting surface of the light source.

3. The light emitting device according to claim 1, wherein:
in the top view, a position of the opening when the light shielding member is in the first position does not overlap a position of the opening when the light shielding member is in the second position.

4. The light emitting device according to claim 1, wherein:
each of the first condition and the second condition is a condition for performing one or both of turning-on of the light source and turning-off of the light source.

5. The light emitting device according to claim 1, wherein:
the light source comprises:
a light emitting element, and
at least one wavelength conversion member located on the light emitting element such that an entirety of the light emitting element is covered in the top view, and
the at least one wavelength conversion member constitutes the light emitting surface of the light source.

6. The light emitting device according to claim 1, wherein:
the light source comprises:
a light emitting element, and
at least one wavelength conversion member located on the light emitting element such that a portion of the light emitting element is exposed in the top view, and
the at least one wavelength conversion member and the light emitting element constitute the light emitting surface of the light source.

7. The light emitting device according to claim 5, wherein:
the at least one wavelength conversion member comprises a plurality of wavelength conversion members having different peak emission wavelengths, and
the wavelength conversion members are located at positions that do not overlap each other in the top view.

8. The light emitting device according to claim 6, wherein:
the at least one wavelength conversion member comprises a plurality of wavelength conversion members having different peak emission wavelengths, and
the wavelength conversion members are located at positions that do not overlap each other in the top view.

9. The light emitting device according to claim 1, wherein:
the light shielding member comprises:
a light transmissive member, and
a light shielding film located on the light transmissive member, and
a region of the light transmissive member on which the light shielding film is not located serves as the opening.

10. The light emitting device according to claim 1, wherein:
the light source comprises a light emitting element, and
a wavelength conversion member is located in the opening of the light shielding member.

11. The light emitting device according to claim 1, wherein:
the light source comprises a plurality of light emitting parts having respective light emitting surfaces, and
the light shielding member has a plurality of openings corresponding to the plurality of light emitting parts.

12. The light emitting device according to claim 11, further comprising:
a wall located around each of the plurality of openings in the top view, wherein:
at least a portion of the wall is located between the light source and the light shielding member.

13. The light emitting device according to claim 11, further comprising:
a plurality of partition walls, wherein:
the plurality of light emitting parts respectively include the plurality of light emitting elements, and
the plurality of partition walls are respectively located around the plurality of light emitting elements in the top view.

14. The light emitting device according to claim 1, wherein:
the opening of the light shielding member overlaps the light emitting surface of the light source, and the light shielding member is movable between a plurality of positions that include the first position and the second position, and
the light emission of the light source is controllable in synchronization with the opening being located at each of the plurality of positions.

15. The light emitting device according to claim 14, wherein:
the light shielding member is configured to make a circulating movement between the plurality of positions, and
a period of time during which the light shielding member moves from the first position to the second position is shorter than a cycle of the circulating movement of the light shielding member.

16. The light emitting device according to claim 15, wherein:
the cycle of the circulating movement of the light shielding member is a natural number multiple of the period of time during which the light shielding member moves from the first position to the second position.

17. The light emitting device according to claim 1, further comprising:
an actuator configured to drive the light shielding member.

18. The light emitting device according to claim 17, wherein:
the actuator includes a piezoelectric element.
